(19) United States
(12) Patent Application Publication
(10) Pub. No.: US 2010/0155131 A1
(43) Pub. Date: Jun. 24, 2010

(54) ELECTRONIC FABRIC AND ELECTRONIC DEVICE USING THEREOF

(75) Inventor: Chien-Ming Fan, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/608,967

(22) Filed: Oct. 29, 2009

(30) Foreign Application Priority Data
Dec. 19, 2008 (TW) 97149742

(51) Int. Cl. H05K 9/00

(52) U.S. Cl. 174/378

(57) ABSTRACT

An electronic fabric for an electronic device, the electronic device comprising a plurality of surfaces, the electronic fabric includes a conductive layer, an adhesive layer and a protective layer. The conductive layer is configured for absorbing electromagnetic interference (EMI) and conduct static electricity from the electronic device when the conductive layer is electrically grounded. The adhesive layer is positioned on the conductive layer, and is configured for adhering the conductive layer to the electronic device. The protective layer is mounted on the adhesive layer, and is configured for protecting the adhesive character of the adhesive layer. The protective layer is separated into many parts corresponding to the plurality of surfaces of the electronic device, and each part can be peeled off separately from the adhesive layer, as the electronic fabric is wrapped on the plurality of surfaces of the electronic device.

### BACKGROUND

1. Technical Field

The present disclosure relates to the electromagnetic shielding, and, particularly, to an electronic fabric shield for an electronic device.

2. Description of Related Art

An electronic fabric may be used to shield an electronic device from electromagnetic interference (EMI). The electronic fabric is also usually grounded thereby discharging static electricity harmlessly to ground.

The electronic fabric is commonly positioned on a surface of the electronic device using an adhesive. Because of the irregular shape of most electronic devices, it is difficult to use one continuous piece of electronic fabric to enclose the entire surface of the electronic device. Therefore, more than one piece of electronic fabrics are connected together to form one patchwork electronic fabric. However, cracks usually develop between the jointed section of the patchwork electronic fabric, resulting in poor electrical connection between the pieces of the patchwork electronic fabric. Thus, protection from EMI and conduction of static electricity of the patchwork electronic fabric, as a whole, may not be acceptable.

Therefore, there is room for improvement in the art.

### BRIEF DESCRIPTION OF THE DRAWINGS

FIG. 1 is an isometric view of an electronic device according to an exemplary embodiment.

FIG. 2 is an isometric view of an electronic fabric corresponding to the electronic device of FIG. 1.

FIG. 3 is a partially schematic and cross-sectional view of the electronic fabric of FIG. 2.

FIG. 4 is an isometric view of the electronic device of FIG. 1 using the electronic fabric of FIG. 2.

FIG. 5 is a partially schematic and cross-sectional view of the electronic fabric of FIG. 4.

### DETAILED DESCRIPTION

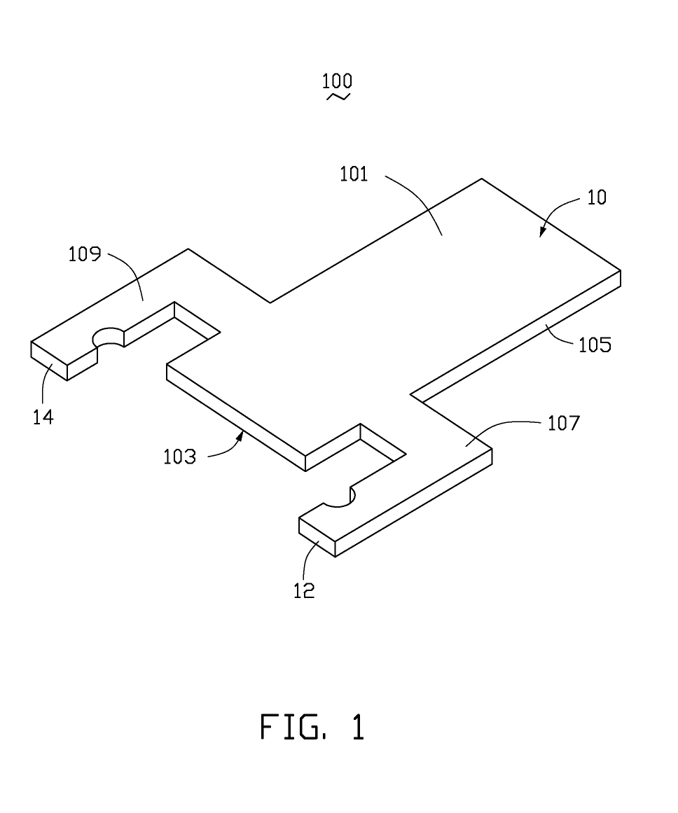

Referring to FIG. 1, an isometric view of an electronic device 100, such as a flexible printed circuit (FPC), is shown according to an exemplary embodiment. The electronic device 100 includes a body 10, a first flap member 12, and a second flap member 14 similar to the first flap member 12.

The body 10 includes a first surface 101, a second surface 103 opposite to the first surface 101, and a third surface 105 connecting the first surface 101 and the second surface 103. In the exemplary embodiment, the third surface 105 is shown as a right side surface.

The first flap member 12 extends from the right side of the body 10, and the second flap member 14 extends from a left side of the body 10. The first flap member 12 includes a fourth surface 107 extending from the first surface 101. The second flap member 14 includes a fifth surface 109 extending from the first surface 101.

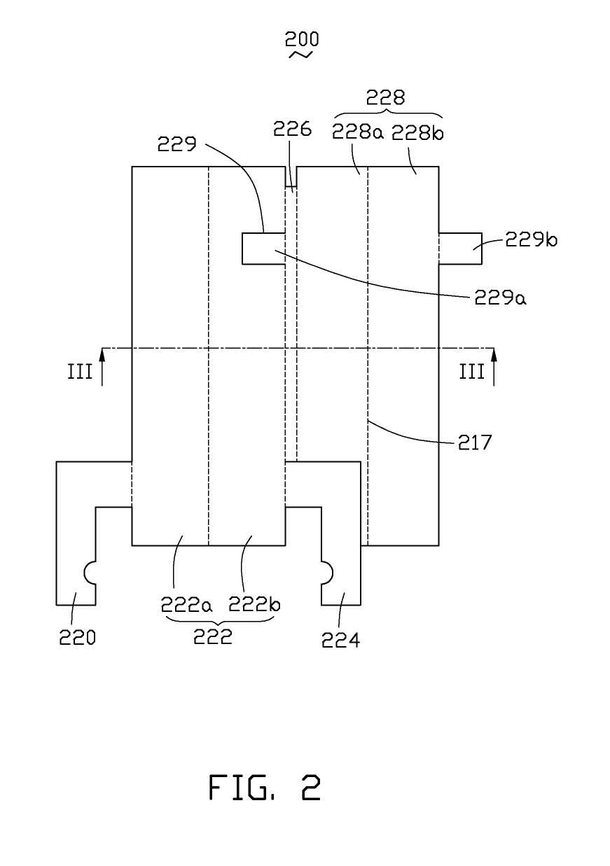

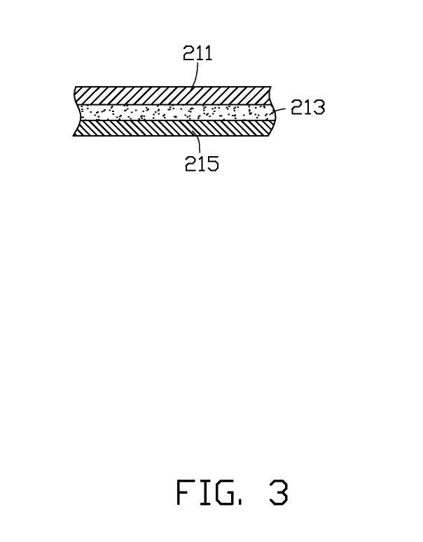

Referring to FIGS. 2 and 3, an electronic fabric 200, as one continuous piece, is shown. The electronic fabric 200 is attached to the electronic device 100, and configured for absorbing electromagnetic interference (EMI) and discharging static electricity from the electronic device 100 when the electronic fabric 200 is electrically grounded.

The electronic fabric 200 includes a conductive layer 211, an adhesive layer 213, and a protective layer 215. The conductive layer 211 is configured for being electrically grounded and for absorbing electromagnetic interference (EMI). The adhesive layer 213 is arranged between the conductive layer 211 and the protective layer 215, and is configured for adhering the conductive layer 211 to the electronic device 100. The protective layer 215 is configured for protecting the adhesive character of the adhesive layer 213. The smoothness of the conductive layer 211 is less than that of the protective layer 215, so an adhesive force between the conductive layer 211 and the adhesive layer 213 is stronger than that between the adhesive layer 213 and the protective layer 215. As such, the protective layer 215 can be peeled off from the adhesive layer 213 easily when the electronic fabric 200 needs to adhere to the electronic device 100 using the adhesive layer 213. Numerous split lines 217 are defined on the protective layer 215, and the protective layer 215 is separated into many parts correspondingly. As a result, each part can be peeled off separately.

According to the split lines 217 of the protective layer 215, the electronic fabric 200 includes a first bonding portion 220 corresponding to the fifth surface 109, a second bonding portion 222 corresponding to the first surface 101, a third bonding portion 224 corresponding to the fourth surface 107, a fourth bonding portion 226 corresponding to the third surface 105, and a fifth bonding portion 228 corresponding to the second surface 103. The second bonding portion 222 includes a first bonding sub-portion 222a and a second bonding sub-portion 222b. The second bonding sub-portion 222b connects the first bonding sub-portion 222a to the fourth bonding portion 226. A U-shaped secant line 229 is arranged on the second bonding sub-portion 222b, and the hatch of the U-shaped secant line 229 faces the fourth bonding portion 226. The U-shaped secant line 229 forms a first ground 229a. The first grounding part 229a is configured for electrically connecting to ground. The third bonding portion 224 is separated from the fifth bonding portion 228 and the fourth bonding portion 226. The fifth bonding portion 228 includes a third bonding sub-portion 228a and a fourth bonding sub-portion 228b. The third bonding sub-portion 228a connects the fourth bonding portion 226 to the fourth bonding sub-portion 228b. A second grounding part 229b extends from the fourth bonding sub-portion 228 and is configured for electrically connecting to ground.

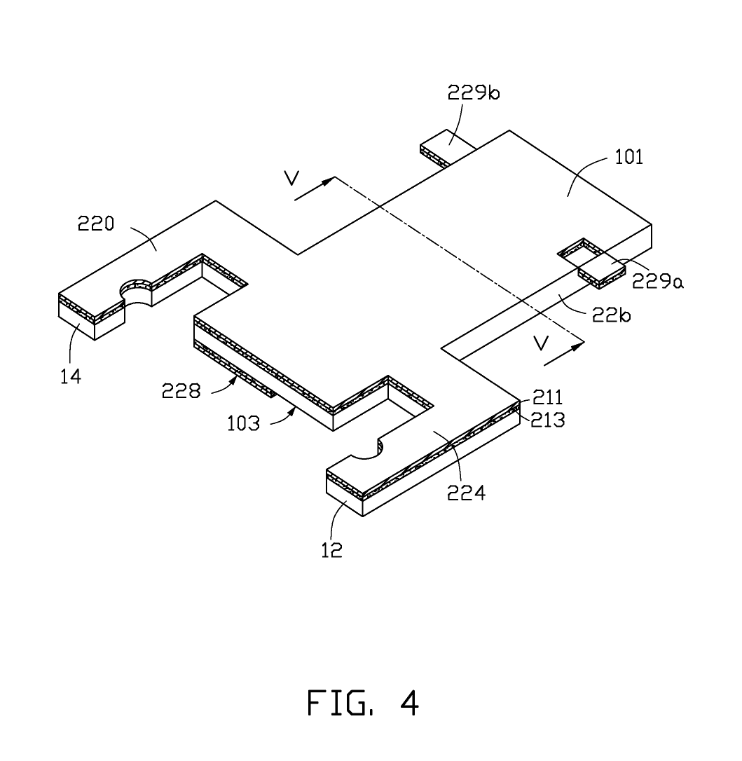

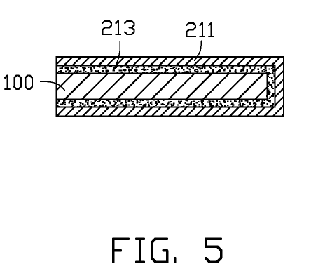

Further referring to FIGS. 4 and 5, the electronic fabric 200 adheres to the electronic device 100 according to the following steps. The first step is to peel off the part of the protective layer 215 corresponding to the second bonding sub-portion 222b, and adhere the electronic fabric 200 to the first surface 101 adjacent to the first flap member 12. The second step is to peel off the part of the protective layer 215 corresponding to the first bonding sub-portion 222a, and adhere the electronic fabric 200 to the first surface 101 adjacent to the second flap member 14. The third step is to peel off the part of the protective layer 215 corresponding to the first bonding portion 220, and adhere the electronic fabric 200 to the fifth surface 109. The fourth step is to peel off the part of the protective layer 215 corresponding to the third bonding portion 224, and adhere the electronic fabric 200 to the fourth surface 107. The fifth step is to peel off the part of the protective layer 215 corresponding to the third bonding sub-portion 228a, and adhere the electronic fabric 200 to the second surface 103 adjacent to the first flap member 12. The sixth step is to peel off the part of the protective layer 215 corresponding to the fourth bonding sub-portion 228b, and adhere the electronic fabric 200 to the second surface 103 adjacent to the second flap member 14. Thereby, the electronic fabric 200 is mounted on the electronic device 100.

To sum up, the protective layer 215 of the electronic fabric 200 is separated into many parts corresponding to the electronic device 100. When the electronic fabric 200 needs to adhere to the electronic device 100, the protective layer 215 can be easily peeled off one by one, and then the electronic fabric 200 is mounted on the electronic device 100 in the peeling order of the protective layer 215. Thus, the electrical connection between the electronic fabric 200 and the electronic device 100 is improved. The electronic fabric 200 will have good electrical connections because the electronic fabric 200 is used as an entirety. Also, because the first grounding part 229a and the second grounding part 229b are arranged on the electronic fabric 200, the function of shielding from the EMI and conduction of static charges is greatly improved.

It is to be understood, however, that even though numerous has been described with reference to particular embodiments, but the present invention is not limited to the particular embodiments described and exemplified, and the embodiments are capable of considerable variation and modification without departure from the scope of the appended claims.

What is claimed is:

1. An electronic fabric for an electronic device, the electronic device comprising a plurality of surfaces, the electronic fabric comprising:
a conductive layer configured for absorbing electromagnetic interference (EMI) and conduct static electricity from the electronic device when the conductive layer is electrically grounded;
an adhesive layer positioned on the conductive layer, and configured for adhering the conductive layer to the electronic device; and
a protective layer mounted on the adhesive layer, and configured for protecting the adhesive character of the adhesive layer, the protective layer is separated into many parts corresponding to the plurality of surfaces of the electronic device, and each part can be peeled off separately from the adhesive layer, as the electronic fabric is wrapped on the plurality of surfaces of the electronic device.

2. The electronic fabric of claim 1, wherein the electronic device comprises:
a body, comprising: a first surface, a second surface opposite to the first surface, and a third surface connecting the first surface and the second surface at a right side of the body;
a first flap member extending from a right side of the body, the first flap member comprising a fourth surface extending from the first surface; and
a second flap member extending from a left side of the body, the second flap member comprising a fifth surface extending from the first surface.

3. The electronic fabric of claim 2, wherein the electronic fabric comprises:
a first bonding portion corresponding to the fifth surface;
a second bonding portion corresponding to the first surface;
a third bonding portion corresponding to the fourth surface;
a fourth bonding portion corresponding to the third surface; and
a fifth bonding portion corresponding to the second surface, and being separated from the third bonding portion.

4. The electronic fabric of claim 3, wherein the second bonding portion comprises a first bonding sub-portion and a second bonding sub-portion, the first bonding sub-portion connects to the first bonding portion, the second bonding sub-portion connects to the third bonding portion and the fourth bonding portion.

5. The electronic fabric of claim 4, wherein a U-shaped secant line is arranged on the second bonding sub-portion, and the hatch of the U-shaped secant line faces the fourth bonding portion, the U-shaped secant line forms a first grounding part, and the first grounding part is configured for electrically connecting to ground.

6. The electronic fabric of claim 4, wherein the fifth bonding portion comprises a third bonding sub-portion and a fourth bonding sub-portion, the third bonding sub-portion is connected between the fourth bonding portion and the fourth bonding sub-portion.

7. The electronic fabric of claim 6, wherein a second grounding part extends from the fourth bonding sub-portion, and is configured for electrically connecting to ground.

8. The electronic fabric of claim 6, wherein the electronic fabric adheres to the electronic device according to the following steps: the first step, peeling off the part of the protective layer corresponding to the second bonding sub-portion of the second bonding portion, and adhering the electronic fabric to the first surface adjacent to the first flap member; the second step, peeling off the part of the protective layer corresponding to the first bonding sub-portion of the second bonding portion, and adhering the electronic fabric to the first surface adjacent to the second flap member; the third step, peeling off the part of the protective layer corresponding to the first bonding portion, and adhering the electronic fabric to the fifth surface; the fourth step, peeling off the part of the protective layer corresponding to the third bonding portion, and adhering the electronic fabric to the fourth surface; the fifth step, peeling off the part of the protective layer corresponding to the third sub-bonding portion of the third bonding portion, and adhering the electronic fabric to the second surface adjacent to the first flap member; the sixth step, peeling off the part of the protective layer corresponding to the fourth sub-bonding portion of the third bonding portion, and adhering the electronic fabric to the second surface adjacent to the second flap member.

9. The electronic fabric of claim 1, wherein split lines are defined on the protective layer to form the parts.

10. An electronic device comprising a plurality of surfaces, the plurality of surfaces can be wrapped by an electronic fabric, the electronic fabric configured for absorbing electromagnetic interference (EMI) and discharging static electricity from the electronic device when the electronic fabric is electrically grounded.

11. The electronic device of claim 10, wherein the electronic fabric comprises:
a conductive layer configured for being electrically connected to ground to shield the electronic device from EMI and static electricity;
an adhesive layer positioned on the conductive layer, and configured for adhering the conductive layer to the electronic device; and
a protective layer mounted on the adhesive layer, and configured for protecting the adhesive character of the adhesive layer, the protective layer is separated into many parts corresponding to the plurality of surfaces of the electronic device, and each part can be peeled off respectively from the adhesive layer, as the electronic fabric is wrapped on the plurality of surfaces of the electronic device.

12. The electronic device of claim 11, wherein split lines are defined on the protective layer to form the parts.

13. The electronic device of claim 10, wherein the electronic device comprises:
a body, comprising: a first surface, a second surface opposite to the first surface, and a third surface connecting the first surface and the second surface at a right side of the body;
a first flap member extending from a right side of the body, the first flap member comprising a fourth surface extending from the first surface; and
a second flap member extending from a left side of the body, the second flap member comprising a fifth surface extending from the first surface.

14. The electronic device of claim 13, wherein the electronic fabric comprises:
a first bonding portion corresponding to the fifth surface;
a second bonding portion corresponding to the first surface;
a third bonding portion corresponding to the fourth surface;
a fourth bonding portion corresponding to the third surface; and
a fifth bonding portion corresponding to the second surface, and being separated from the third bonding portion.

15. The electronic device of claim 14, wherein the second bonding portion comprises: a first bonding sub-portion and a second bonding sub-portion, the first bonding sub-portion connects to the first bonding portion, the second bonding sub-portion connects to the third bonding portion and the fourth bonding portion.

16. The electronic device of claim 15, wherein a U-shaped secant line is arranged on the second bonding sub-portion, and the hatch of the U-shaped secant line faces the fourth bonding portion, the U-shaped secant line forms a first grounding part, and the first grounding part is configured for electrically connecting to ground.

17. The electronic device of claim 15, wherein the fifth bonding portion comprises: a third bonding sub-portion and a fourth bonding sub-portion, the third bonding sub-portion is connected between the fourth bonding portion and the fourth bonding sub-portion.

18. The electronic device of claim 17, wherein a second grounding part extends from the fourth bonding sub-portion, and configured for electrically connecting to ground.

19. The electronic device of claim 17, wherein the electronic fabric adheres to the electronic device according to the following steps: the first step, peeling off the part of the protective layer corresponding to the second bonding sub-portion of the second bonding portion, and adhering the electronic fabric to the first surface adjacent to the first flap member; the second step, peeling off the part of the protective layer corresponding to the first bonding sub-portion of the second bonding portion, and adhering the electronic fabric to the first surface adjacent to the second flap member; the third step, peeling off the part of the protective layer corresponding to the first bonding portion, and adhering the electronic fabric to the fifth surface; the fourth step, peeling off the part of the protective layer corresponding to the third bonding portion, and adhering the electronic fabric to the fourth surface; the fifth step, peeling off the part of the protective layer corresponding to the third sub-bonding portion of the third bonding portion, and adhering the electronic fabric to the second surface adjacent to the first flap member; the sixth step, peeling off the part of the protective layer corresponding to the fourth sub-bonding portion of the third bonding portion, and adhering the electronic fabric to the second surface adjacent to the second flap member.
